(19) United States
(12) Patent Application Publication
(10) Pub. No.: US 2017/0273180 A1
(43) Pub. Date: Sep. 21, 2017

(54) OVERMOLDED PLASTIC COMPONENTS FORMED ON METALLIC PLATES

(71) Applicant: APPLE INC., Cupertino, CA (US)

(72) Inventors: David J. Drennan, San Francisco, CA (US); Bruce Berg, San Jose, CA (US); Joseph Nazari, La Crescenta, CA (US); Bonnie W. Tom, San Leandro, CA (US); Kristina A. Babiarz, San Jose, CA (US); Anthony P. Grazian, Los Gatos, CA (US)

(73) Assignee: APPLE INC., Cupertino, CA (US)

(21) Appl. No.: 15/157,314

(22) Filed: May 17, 2016

Related U.S. Application Data
(60) Provisional application No. 62/310,161, filed on Mar. 18, 2016.

(51) Int. Cl. H05K 1/05; H04R 1/02; H05K 3/00; H04R 31/00; H05K 1/02; H05K 3/10

(52) U.S. Cl. CPC H05K 1/056; H05K 1/0296; H05K 3/10; H05K 3/0014; H04R 31/006; H04R 1/02; H05K 2201/0137

(57) ABSTRACT

A method of forming an overmolded plastic structure on a metallic plate includes first bonding a component to the metallic plate. The component is bonded with an adhesive that adheres it to the metallic plate. A plastic structure is formed over at least a portion of the component and the metallic plate and the plastic structure primarily adheres to the component. The component can be a set of metallic signal conductors that are used to route electrical signals across the metallic plate and the adhesive can be used to electrically insulate the signal conductors from the metallic plate.

### CROSS REFERENCE TO RELATED APPLICATIONS

This application claims priority to Provisional Application No. 62/310,161, filed Mar. 18, 2016, titled “OVERMOLDED PLASTIC COMPONENTS FORMED ON METALLIC PLATES”, which is hereby incorporated by reference in its entirety for all purposes.

### FIELD

The described embodiments relate generally to overmolded plastic structures formed on metallic plates.

### BACKGROUND

In many applications it's useful to form one or more overmolded plastic structures on a metallic plate. It is common in such overmolding processes to form penetrations through, form stamped features on or perform surface preparation on the metallic plate to securely lock the plastic overmold to the metallic plate. Without such processes, reliable adhesion of the overmolded plastic to the metallic plate can be a challenge, and the plastic can delaminate from the metallic plate. In some instances, however, it can be desirable to overmold a plastic structure on a metallic plate without having penetrations formed through the plate and without performing additional surface preparation steps on the metallic plate to improve adhesion.

### SUMMARY

Some embodiments of the present invention relate to methods of forming overmolded plastic structures on metallic plates. In some embodiments a component is first bonded to a metallic plate with an adhesive, then an overmolded plastic structure is formed over the component and a portion of the metallic plate. The overmolded plastic structure is configured to predominantly adhere to the component which is held to the metallic plate with the adhesive.

Some embodiments relate to methods of forming and securing an overmolded plastic structure on a metallic plate, where the method comprises first forming the metallic plate and forming a component. The component is bonded to the metallic plate with an adhesive and an overmolded plastic structure is formed over at least a portion of the component and on at least a portion of the metallic plate. In various embodiments the component comprises one or more metallic signal conductors.

In some embodiments the overmolded plastic structure forms one or more speaker driver housings and the one or more metallic signal conductors couple electrical signals to the one or more speaker driver housings. In various embodiments the one or more metallic signal conductors are secured together with one or more plastic unions. In some embodiments the adhesive is a pressure sensitive acrylic. In various embodiments the adhesive includes an electrically insulative layer and an adhesive disposed on both faying surfaces of the electrically insulative layer.

In some embodiments the portion of the metallic plate over which the overmolded plastic structure is formed is substantially solid without any holes or perforations formed therethrough. In various embodiments the overmolded plastic structure includes a polycarbonate material.

In some embodiments a composite structure comprises a metallic plate, a component, an adhesive disposed between at least a portion of the component and the metallic plate such that the component is bonded to the metallic plate and an overmolded plastic structure formed over at least a portion of the component and on at least a portion of the metallic plate.

In some embodiments the component comprises one or more metallic signal conductors. In various embodiments the overmolded plastic structure forms one or more speaker driver housings and the one or more metallic signal conductors couple electrical signals to the one or more speaker driver housings. In some embodiments the portion of the metallic plate over which the plastic overmold structure is formed is substantially solid without any holes or perforations formed therethrough. In various embodiments the adhesive is a pressure sensitive acrylic.

In some embodiments an assembly for routing electrical signals comprises a metallic plate and one or more metallic signal conductors bonded to the metallic plate with an adhesive that provides electrical insulation between the one or more metallic signal conductors and the metallic plate. An overmolded plastic structure is formed around at least a portion of the one or more metallic signal conductors and on at least a portion of the metallic plate.

In some embodiments the plastic structure forms at least a portion of one or more speaker driver housings. In various embodiments the plastic structure forms at least a portion of one or more acoustic chambers. In some embodiments the one or more metallic signal conductors couple electrical signals to the one or more speaker driver housings. In various embodiments the overmolded plastic structure is a polycarbonate material.

In some embodiments the adhesive includes an electrically insulative layer having a first adhesive layer disposed between the metallic plate and the insulative layer and a second adhesive layer disposed between the one or more metallic signal conductors and the insulative layer. In various embodiments the first and the second adhesive layers include a pressure sensitive acrylic.

To better understand the nature and advantages of the present invention, reference should be made to the following description and the accompanying figures. It is to be understood, however, that each of the figures is provided for the purpose of illustration only and is not intended as a definition of the limits of the scope of the present invention. Also, as a general rule, and unless it is evident to the contrary from the description, where elements in different figures use identical reference numbers, the elements are generally either identical or at least similar in function or purpose.

### BRIEF DESCRIPTION OF THE DRAWINGS

FIG. 1 is a front perspective view of a metallic plate with a component bonded to it and a plastic structure formed over at least a portion of the metallic plate and the component according to an embodiment of the invention;

FIG. 2 is a method by which the assembly shown in FIG. 1 can be made;

FIG. 3A is an isometric view of a portable computing device showing a speaker region;

FIG. 3B is an isometric view of a computing device with an integrated speaker assembly according to an embodiment of the invention;

FIG. 4 is an isometric view of a set of signal conductors that are a part of the integrated speaker assembly illustrated in FIG. 3B;

FIG. 5 is an isometric view of the set of signal conductors illustrated in FIG. 4 with unions formed around portions of the signal conductors;

FIG. 6 is an isometric view of the signal conductors illustrated in FIG. 5 being prepared to be bonded to a metallic plate with an adhesive;

FIG. 7 is an isometric view of the signal conductors illustrated in FIG. 5 bonded to a metallic plate with an adhesive;

FIG. 8 is an isometric view of the signal conductors and the metallic plate illustrated in FIG. 7 with a plastic structure formed over a portion of the signal conductors and a portion of the metallic plate;

FIG. 9 is a cross section of the assembly illustrated in FIG. 8; and

FIG. 10 is a method of by which the assembly illustrated in FIG. 9 can be manufactured.

### DETAILED DESCRIPTION

Some embodiments of the present invention relate to methods of forming overmolded plastic structures on metallic plates where the plastic is securely adhered to the metallic plate without having penetrations formed through the metallic plate and without performing an extra surface preparation step on the metallic plate to promote adhesion prior to the overmolding step.

Some embodiments relate to methods of first bonding a component to a metallic plate with an adhesive, then forming an overmolded plastic structure over the component and a portion of the metallic plate. The overmolded plastic structure can be configured to predominantly adhere to the component which is held to the metallic plate with the adhesive.

In some embodiments the adhesive can further act as a coefficient of expansion accommodation layer between the overmolded plastic structure and the metallic plate so the bonded assembly does not warp or bow while it cools from the overmolding process. While the present invention can be useful for a wide variety of configurations, some embodiments of the invention are particularly useful for electronic devices that use internal speaker driver assemblies, as described in more detail below.

As an example, an electronic device can have an internal speaker assembly that holds one or more speaker drivers and is configured to couple electronic signals to the one or more speaker drivers. According to some embodiments of the disclosure, a metallic plate can be used for a base of the speaker assembly and metallic signal conductors can be formed and bonded to the metallic plate with an electrically insulative adhesive. Plastic speaker driver housings can then be overmolded over portions of the metallic signal conductors and portions of the plate so speaker drivers can be mounted to the overmolded plastic speaker housings and electrically connected to the metallic signal conductors. The overmolded plastic speaker driver housings can be configured to predominantly adhere to the signal conductors rather than the metallic plate.

Additionally, in some embodiments the adhesive used to bond the metallic signal conductors to the metallic plate can have additional benefits other than just adhering the signal conductors to the metallic plate. In various embodiments the adhesive can also function as a stress relief layer, relieving thermally induced stresses between the overmolded plastic speaker housings and the metallic plate. Further, in some embodiments the adhesive can also function as an acoustic seal for a speaker back volume or a speaker cavity. In yet further embodiments an insulative layer can be integrated within the adhesive to insure electrical isolation between the signal conductors and the metallic plate

In order to better appreciate the features and aspects of overmolded plastic structures on metallic plates according to the present invention, further context for the invention is provided in the following section by discussing a generic implementation followed by one particular implementation of such structures according to embodiments of the present invention. These embodiments are for example only and other embodiments can be employed in other applications as well as other electronic devices such as, but not limited to computers, portable media devices, watches, media players, toys, mechanisms and other devices.

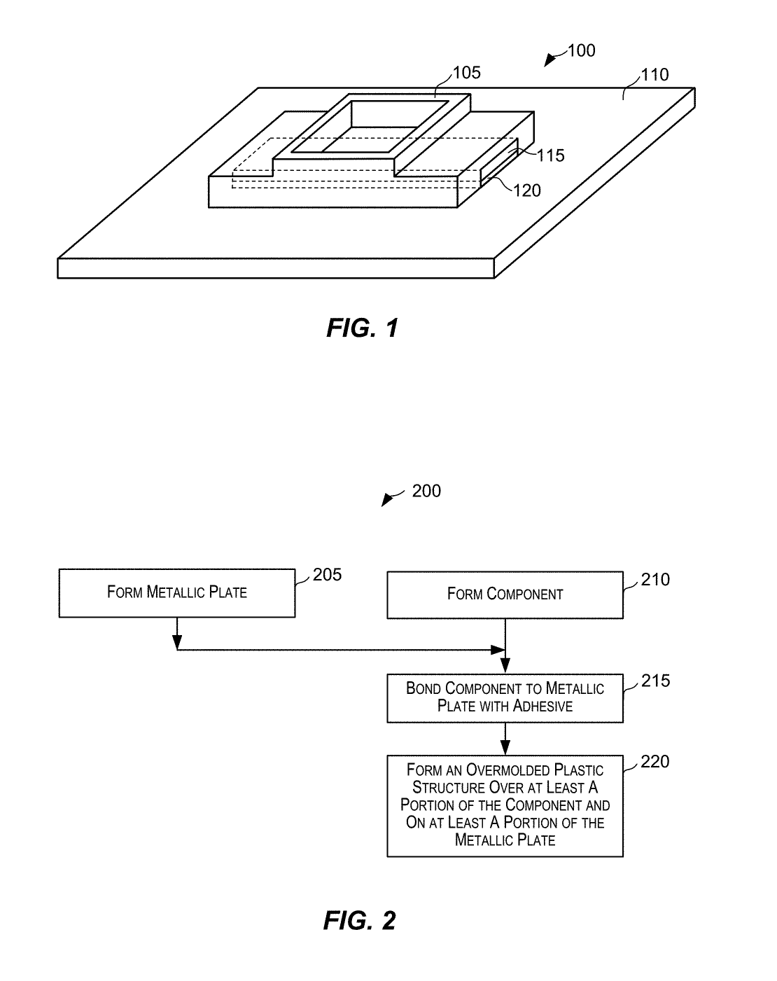

Reference is now made to FIGS. 1 and 2 with respect to a generic implementation of an assembly 100 that includes an overmolded plastic structure 105 formed on a metallic plate 110. Assembly 100 is a generic illustration that is intended to represent the general concept of the invention and its breadth of applicability to myriad applications. FIG. 1 is a simplified perspective view of assembly 100 while FIG. 2 is a flow chart that illustrates general steps associated with a method of manufacturing 200 assembly 100 according to some embodiments of the disclosure.

In a first step of the manufacture of assembly 100 (step 205 of FIG. 2), metallic plate 110 is formed. Metallic plate 110 can be made of any metal or alloy, can be relatively continuous and may not have any penetrations or special surface preparation to promote adhesion of overmolded plastic structure 105. In some embodiments metallic plate 110 is made from stainless steel.

In a second step (step 210 of FIG. 2), a component 115 is formed. Component 115 in FIG. 1 has a generally rectangular shape that is considerably longer than it is wide, similar to a strip. The shape of component 115 in FIG. 1 is for example purposes only. Component 115 can have many other shapes or configurations and in various embodiments there can be more than one component. In some embodiments component 115 can be made from a plastic, while in other embodiments it can be made from any other material such as, for example, a metal that can be electrically conductive, as discussed in more detail below. In some embodiments component 115 can have one or more features that assist its adherence to other materials such as an adhesive or an overmolded plastic. For example, in some embodiments component 115 can have one or more roughened surfaces and/or one or more geometrical features (e.g., such as holes, chamfered edges, undercuts, flanges, bevels, etc.) to increase its effective surface area and/or create locking features to improve its ability to bond to another component. First step 205 and second step 210 are not sequential and may be performed in any order.

In a third step (step 215 of FIG. 2), component 115 is bonded to metallic plate 110 with an adhesive 120. Adhesive 120 can be any type of glue, epoxy or other bonding material. In one embodiment adhesive 120 can be, for example, a pressure sensitive acrylic or a silicone-based adhesive. In some embodiments adhesive 120 can be configured to withstand subsequent overmolding temperatures and relieve thermally induced stresses between component 115 and metallic plate 110, as discussed in more detail below. In various embodiments adhesive 120 can also have an integrated insulative layer or “scrim” as also discussed in more detail below. Adhesive 120 is disposed between at least a portion of component 115 and metallic plate 110 and cured, such that it bonds the component to the metallic plate.

In a fourth step (step 220 of FIG. 2), overmolded plastic structure 105 is formed over at least a portion of component 115 and on at least a portion of metallic plate 110. The overmolding process can be performed by placing metallic plate 110 with component 115 bonded to it within an injection molding tool and injection molding the overmolded plastic structure 105 over the component. This process can also be known as insert-molding. Any type of plastic material can be used to form overmolded plastic structure 105, such as for example, a ten percent glass filled polycarbonate material. During the molding process, the molten plastic material can flow around component 115 and bond to component 115 such that overmolded plastic structure 105 primarily adheres to the component, rather than metallic plate 110. Thus, adhesive 120 can be the primary structural means holding overmolded plastic structure 105 to metallic plate 110.

In some embodiments, adhesive 120 can also act as a coefficient of expansion (CTE) accommodation layer between component 115 and metallic plate 110 so assembly 100 does not warp or bow while it cools from the injection molding process. More specifically, typically the overmolding process is performed at elevated temperatures that can be above 100° Centigrade. After forming overmolded plastic structure 105, assembly 100 is cooled and the overmolded plastic structure can shrink faster than metallic plate 110 causing assembly 100 to bow or warp if the two were rigidly bonded. However, adhesive 120 can be selected to have a sufficiently low shear modulus of elasticity within the cooling down temperature range such that it relieves a substantial portion of the thermally induced stresses so assembly 100 remains substantially flat during the cooling process.

As discussed above, assembly 100 is a generic example of an overmolded plastic component on a metallic plate and illustrates the myriad applications of this method. For example, in one embodiment overmolded plastic structure 105 can be used as a battery holder within a toy while in another embodiment it can be used as a latch catch on a metal cabinet. In further embodiments it can function as a speaker driver housing within an electronic device, as discussed in more detail below. Overmolded plastic structure 105 can have any geometry and/or configuration.

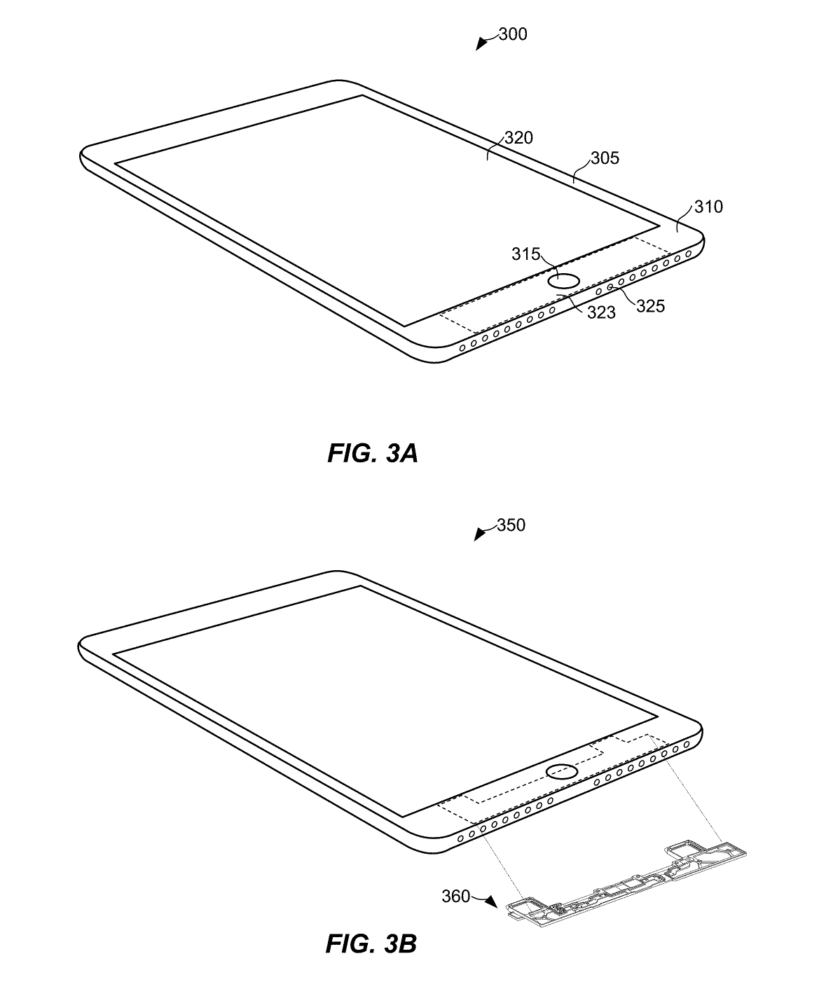

Now referring to FIG. 3A an example electronic device 300 is illustrated that that is a portable computing device such as a tablet computer (e.g., an iPad®). Electronic device 300 includes a housing 305 with exterior surface 310 having a multipurpose button 315 as an input component and a touch screen display 320 as both an input and output component. In some embodiments electronic device 300 can also have one or more speakers located within speaker region 323 that are configured to communicate through apertures 325 in exterior surface 310.

Current methods of coupling electrical signals from the internal circuitry of electronic device 300 to the one or more speakers includes routing insulated metal wires through the internal assembly or attaching flexible or rigid circuit boards to the internal assembly. Such methods can include a large number of electrical interconnects that can decrease the reliability of the system and further, such methods can be difficult to automate, often including multiple individual components requiring time consuming and expensive manual labor to assemble them.

Reference is now made to FIG. 3B that shows an electronic device 350 including an embodiment of the invention having an integrated speaker assembly 360 providing a single assembly that facilitates automated manufacturing and fewer electrical interconnects than electronic device 300. More specifically, in some embodiments, integrated speaker assembly 360 can include one or more overmolded plastic structures formed on a metallic plate and a plurality of integrated metallic signal conductors configured to conduct electrical signals to the one or more speakers, as described in more detail below.

Embodiments of integrated speaker assembly 360 can be employed in other applications as well as other electronic devices than electronic device 350 such as, but not limited to desktop computers, laptop computers, portable media devices, watches, media players, toys, mechanisms and other devices.

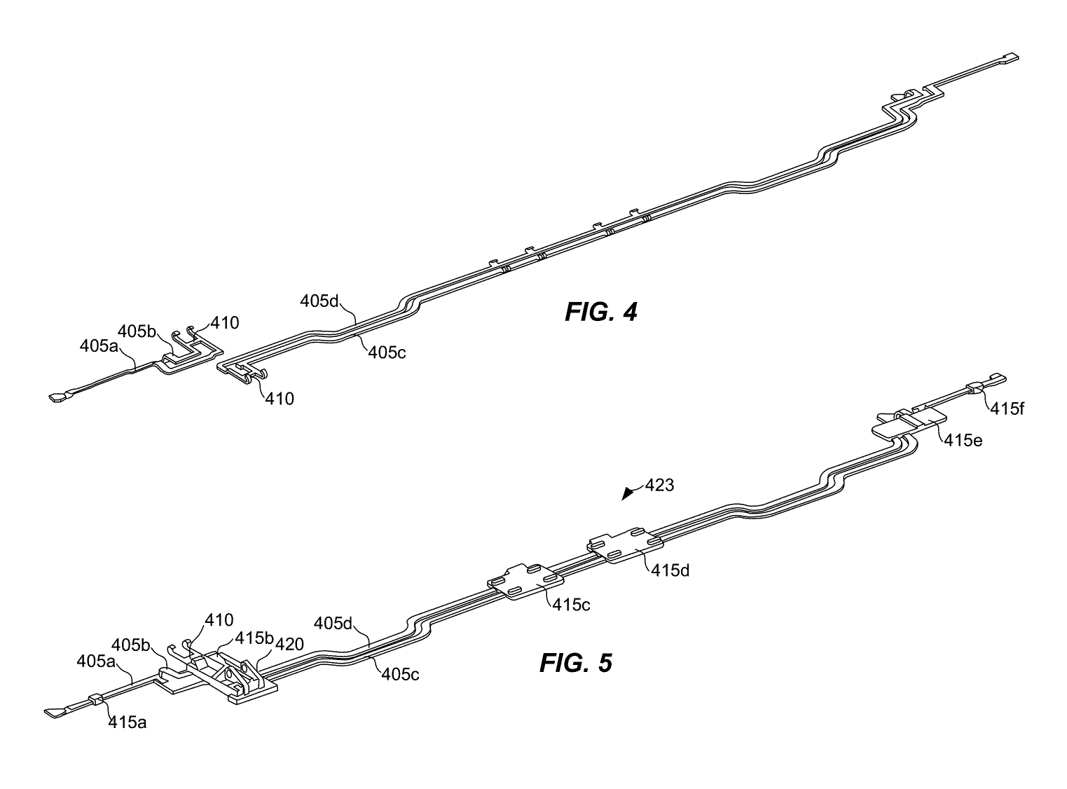

Reference is now made to FIGS. 4-10 regarding the manufacture and assembly of speaker assembly 360 (see FIG. 3) according to one embodiment of the method of the present invention. FIG. 10 is a flow chart that illustrates the general steps associated with the manufacture and assembly of speaker assembly 300 according to one embodiment of the invention. FIGS. 4-9 depict assembly 300 at the various stages of manufacture set forth in FIG. 10.

Now referring to FIG. 4 (step 1005 of FIG. 10) a plurality of metallic signal conductors 405a-405d are formed. Conductors 405a-405d can be made out of any electrically conductive material including a metal and/or metal alloys. In some embodiments, conductors 405a-405d can also be plated with one or more layers of metal. Conductors 405a-405d can be formed by stamping, cutting, electroforming or any other process. In some embodiments, conductors 405a-405d are 0.15 millimeters thick and 0.9 millimeters wide and made from a copper-based material, such as for example, a phosphor-bronze material that is plated with a layer of nickel then a layer of gold. In various embodiments the phosphor-bronze material can be useful to form resilient spring contacts as a portion of conductors 405a-405d, as discussed in more detail below.

In some embodiments, conductors 405a-405d can be held together with one or more tie bars 410 to hold the individual conductors together and in place once they have been formed. In various embodiments, conductors 405a and 405b can conduct electronic signals to a first speaker driver and conductors 405c and 405d conduct signals to a second speaker driver, as discussed in more detail below.

Now referring to FIG. 5 (step 1010 of FIG. 10), an optional first overmolding operation can be performed on conductors 405a-405d forming one or more overmolded plastic unions 415a-415f. In various embodiments, the first overmolding operation can be performed using an insert molding process as discussed above. The plastic can be any plastic material, and in some embodiments it can be a ten percent glass filled polycarbonate. In various embodiments, if the assembly has one or more tie bars 410, they can be removed such that each conductor 405a-405d is electrically isolated from the other conductors and one or more overmolded plastic unions 415a-415f will hold the conductors in place. Tie bar 410 removal can be performed with punching, sawing, laser ablation or any other type of material removal process.

The assembly including overmolded conductors 405a-405d with unions 415a-415f will be referred to as conductor assembly 423 herein. In some embodiments, one or more overmolded plastic unions 415a-415f can function as a mandrel for the formation of spring contacts 420 and alignment aids for subsequent assembly operations. In some embodiments unions 415a-415f can also function as handling aids for conductor assembly 423 so it can be transferred and handled using automated equipment. Thus, the formation of unions 415a-415f on conductors 405a-405d can enable the automated handling of one component rather than each individual signal conductor simplifying the insert molding process. In some embodiments, first overmolding operation (step 1010 of FIG. 10) may not be performed and overmolded plastic unions 415a-415f may not be formed. For example, in various embodiments conductors 405a-405d can be all held together with a plurality of tie bars or an assembly fixture and step 1010 can be skipped.

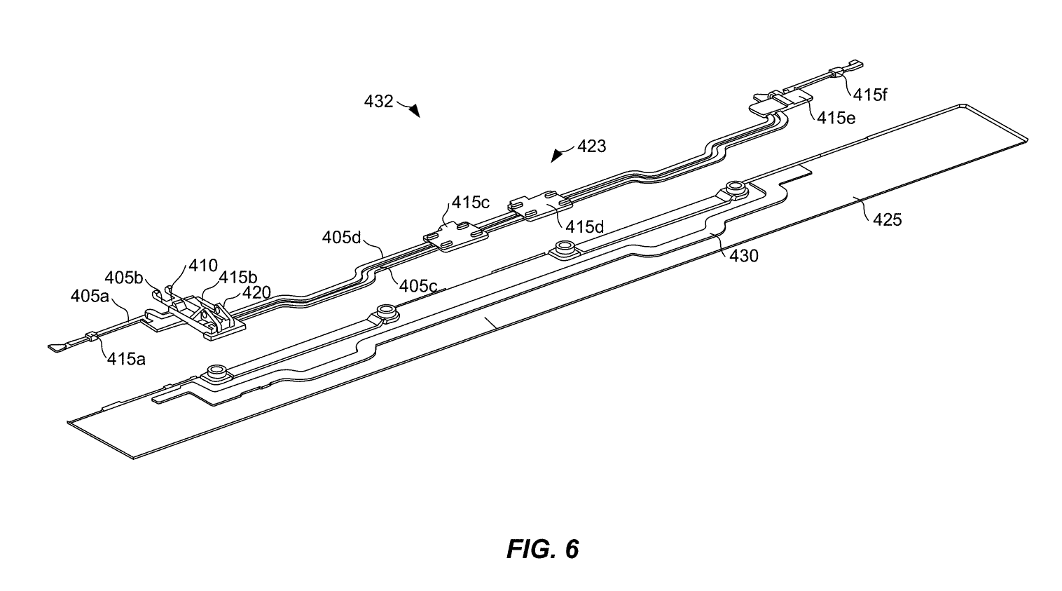

Now referring to FIG. 6 (step 1015 of FIG. 10), metallic plate 425 is formed. Metallic plate 425 can be made of any metal or alloy, can be relatively continuous and may not have any penetrations or special surface preparation to promote adhesion. In some embodiments, metallic plate 425 is made from stainless steel and is formed with a progressive stamping process. The formation of metallic plate 425 may be performed at any time before it is used in subsequent step, 1020.

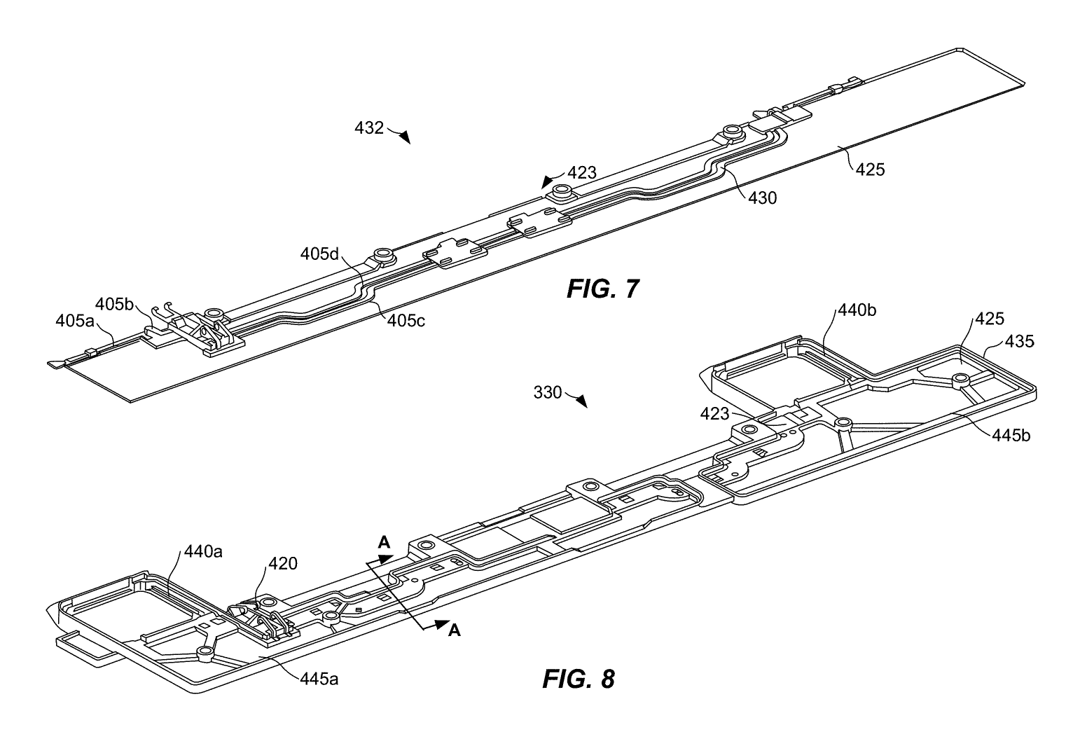

Now referring to FIGS. 6 and 7 simultaneously, (step 1020 of FIG. 10), conductor assembly 423 is bonded to metallic plate 425 with adhesive 430 creating subassembly 432. FIG. 6 illustrates adhesive 430 bonded to metallic plate 425 and FIG. 7 illustrates conductor assembly 423 bonded by the adhesive to the metallic plate. As discussed above, adhesive 430 can be any type of glue, epoxy or other bonding material. In one embodiment adhesive 430 can include a pressure sensitive acrylic layer having a thickness of approximately 30 microns such as, for example, Tessa 8851 manufactured by Tessa Incorporated, disposed on both faying surfaces of a 50 micron thick layer of insulation. The acrylic layers can be used as a bonding agent and the integrated insulation layer of insulation can be used for electrical isolation between conductors 405a-405d and metallic plate 425. The insulation layer may be any electrical insulator and in some embodiments it can be, for example, polyimide or mylar.

In various embodiments adhesive 430 can be, for example, a silicone-based adhesive having a thickness of 100 microns. In some embodiments a silicone adhesive is disposed on metallic plate 425, a 0.1 millimeter insulative plastic mesh is placed on the adhesive and conductors 405a-405d are placed on the mesh (i.e., and in contact with the silicone adhesive so they are bonded to metallic plate 435). Other types, combinations and thicknesses of adhesive 430 and integrated insulation layers, such as mylar, are within the scope of this disclosure. As another example, in one embodiment adhesive 430 can be precut using a die, while in other embodiments it can be dispensed or sprayed onto the mating surfaces. As a further example, in some embodiments the thickness of the bonding agent can be adjusted to minimize squeeze out while being thick enough to provide a reliable bond between the faying surfaces.

As discussed above, in some embodiments adhesive 430 can be configured to withstand subsequent overmolding temperatures and relieve thermally induced stresses between component 425 and metallic plate 425 such that the bonded assembly does not warp or bow as it cools from the overmolding operation discussed below in step 1025. In various embodiments, adhesive 430 can also function as an acoustic sealant for overmolded speaker driver housings, as discussed in more detail below.

Now referring to FIG. 8, (step 1025 of FIG. 10), overmolded plastic structure 435 is formed over at least a portion of conductor assembly 423 and on at least a portion of metallic plate 425 forming integrated speaker assembly 360. The overmolding process can be performed by placing subassembly 432 (see FIG. 7) within an injection molding tool and forming overmolded plastic structure 435 with an injection molding process as described herein. Any plastic material can be used for overmolded plastic structure 435, and in some embodiments a ten percent glass filled polycarbonate material can be employed. The molten plastic material can flow around conductors 405a-405d (see FIG. 7) and unions 415a-415f such that it is primarily secured to these components rather than metallic plate 425. Thus, adhesive 430 can be the primary structural means holding overmolded plastic structure 435 to metallic plate 425.

In some embodiments overmolded plastic structure 435 can include one or more speaker driver housings 440a, 440b and one or more acoustic chambers 445a, 445b. Integrated speaker assembly 360 can include one or more speaker drivers disposed in speaker driver housings 440a, 440b and assembled within electronic device 300 (see FIG. 3). In various embodiments adhesive 430 can be used to aid in forming an acoustic seal for one or more speaker driver housings 440a, 440b and one or more acoustic chambers 445a, 445b mitigating the leakage of air and securing conductor assembly 423 to metallic plate 425 to minimize the acoustic vibration or “buzz” of conductor assembly 423. In further embodiments one or more portions of conductors 405a-405d can be formed into resilient electronic contacts 420 that can be used to couple the conductors to other electronic circuitry within electronic device 300 (see FIG. 3).

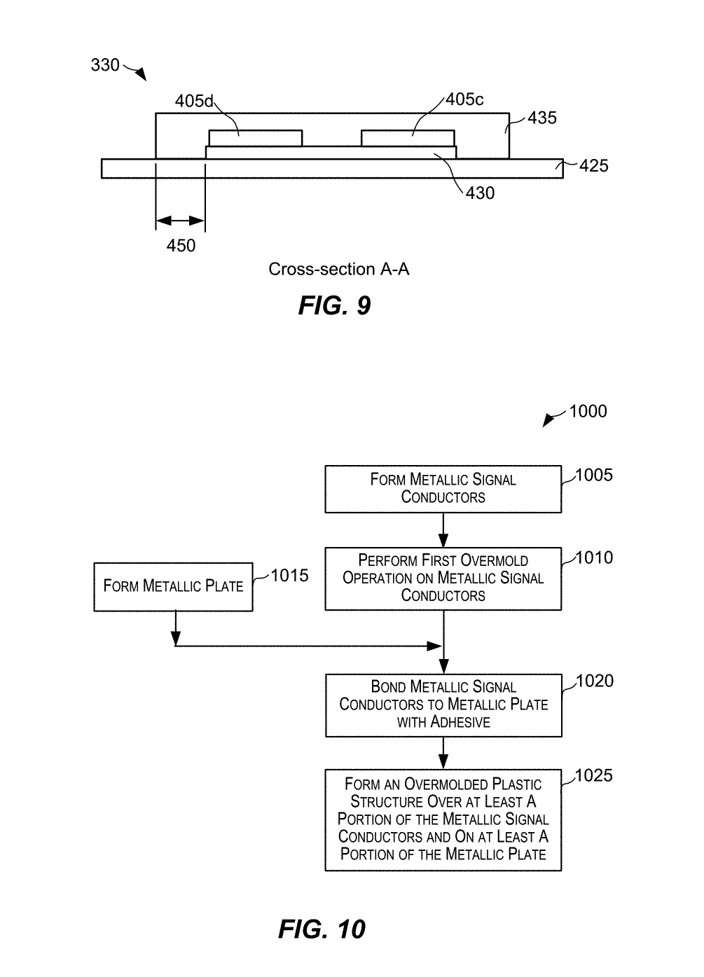

A cross-section A-A of a portion of integrated speaker assembly 360 is illustrated in FIG. 9 and shows conductors 405c, 405d, adhesive 430, metallic plate 425 and overmolded plastic structure 435. In some embodiments a first distance 450 between adhesive 430 and an edge of overmolded plastic structure 435 can be controlled on both sides of conductors 405c, 405d to equalize hydrostatic pressure on adhesive during molding to minimize squeeze out of the adhesive.

In some embodiments conductors 405c, 405d can be configured to transmit high frequency signals such as those used by antenna or data transmission circuits. As an example, in one embodiment conductors 405c, 405d can be configured as microstrip transmission lines where metallic plate 425 functions as a ground plane and adhesive 430 functions as a dielectric. By controlling the dimensions of conductors 405c, 405d, and adhesive 430, the impedance of the conductors can be optimized for a particular frequency band. In further embodiments the amount and type of plastic used for overmolded plastic structure 435 can also be modified for a particular frequency band. As an example, instead of a polycarbonate plastic a nylon or a Teflon material can be used to modify the dielectric constant of the plastic along with other material properties.

In some embodiments the dimensions of conductors 405c, 405d, the space between the conductors, the material properties of adhesive 430 and the material properties of the overmolded plastic can be modified such that the conductors have a designed impedance relative to one another such that high frequency signals can be transmitted. As an example, conductors 405c, 405d can be used as two complementary transmission lines (i.e., a high-speed differential pair) that transfer equal and opposite signals along their length. Such embodiments can be beneficial for high speed flush mount connectors on electronic devices.

Although electronic device 300 (see FIG. 3) is described and illustrated as one particular electronic device, embodiments of the invention are suitable for use with a multiplicity of electronic devices. For example, any device that receives or transmits audio, video or data signals can be used with the invention. In some instances, embodiments of the invention are particularly well suited for use with portable electronic media devices because of their potentially small form factor. In further instances, embodiments of the invention can be suited for flush mount connectors. As used herein, an electronic media device includes any device with at least one electronic component that can be used to present human-perceivable media. Such devices can include, for example, portable music players (e.g., MP3 devices and Apple's iPod devices), portable video players (e.g., portable DVD players), cellular telephones (e.g., smart telephones such as Apple's iPhone devices), video cameras, digital still cameras, projection systems (e.g., holographic projection systems), gaming systems, PDAs, as well as tablet (e.g., Apple's iPad devices), laptop or other mobile computers. Some of these devices can be configured to provide audio, video or other data or sensory output.

For simplicity, various internal components, such as the control circuitry, graphics circuitry, bus, memory, storage device and other components of electronic device 300 (see FIG. 3) are not shown in the figures.

In the foregoing specification, embodiments of the invention have been described with reference to numerous specific details that can vary from implementation to implementation. The specification and drawings are, accordingly, to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction. The specific details of particular embodiments can be combined in any suitable manner without departing from the spirit and scope of embodiments of the invention.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

What is claimed is:

1. A method of forming and securing an overmolded plastic structure on a metallic plate, the method comprising:
forming the metallic plate;
forming a component;
bonding the component to the metallic plate with an adhesive; and
forming an overmolded plastic structure over at least a portion of the component and on at least a portion of the metallic plate.

2. The method of claim 1 wherein the component comprises one or more metallic signal conductors.

3. The method of claim 2 wherein the overmolded plastic structure forms one or more speaker driver housings and the one or more metallic signal conductors couple electrical signals to the one or more speaker driver housings.

4. The method of claim 2 wherein the one or more metallic signal conductors are secured together with one or more plastic unions.

5. The method of claim 1 wherein the adhesive is a pressure sensitive acrylic.

6. The method of claim 1 wherein the adhesive includes an electrically insulative layer and an adhesive disposed on both faying surfaces of the electrically insulative layer.

7. The method of claim 1 wherein the portion of the metallic plate over which the overmolded plastic structure is formed is substantially solid without any holes or perforations formed therethrough.

8. The method of claim 1 wherein the overmolded plastic structure includes a polycarbonate material.

9. A composite structure comprising:
a metallic plate;
a component;
an adhesive disposed between at least a portion of the component and the metallic plate such that the component is bonded to the metallic plate; and
an overmolded plastic structure formed over at least a portion of the component and on at least a portion of the metallic plate.

10. The composite structure of claim 9 wherein the component comprises one or more metallic signal conductors.

11. The composite structure of claim 10 wherein the overmolded plastic structure forms one or more speaker driver housings and the one or more metallic signal conductors couple electrical signals to the one or more speaker driver housings.

12. The composite structure of claim 9 wherein the portion of the metallic plate over which the plastic overmold structure is formed is substantially solid without any holes or perforations formed therethrough.

13. The method of claim 9 wherein the adhesive is a pressure sensitive acrylic.

14. An assembly for routing electrical signals comprising:
a metallic plate;
one or more metallic signal conductors bonded to the metallic plate with an adhesive that provides electrical insulation between the one or more metallic signal conductors and the metallic plate; and
an overmolded plastic structure formed around at least a portion of the one or more metallic signal conductors and on at least a portion of the metallic plate.

15. The assembly of claim 14 wherein the plastic structure forms at least a portion of one or more speaker driver housings.

16. The assembly of claim 14 wherein the plastic structure forms at least a portion of one or more acoustic chambers.

17. The assembly of claim 15 wherein the one or more metallic signal conductors couple electrical signals to the one or more speaker driver housings.

18. The assembly of claim 14 wherein the overmolded plastic structure is a polycarbonate material.

19. The assembly of claim 14 wherein the adhesive includes an electrically insulative layer having a first adhesive layer disposed between the metallic plate and the insulative layer and a second adhesive layer disposed between the one or more metallic signal conductors and the insulative layer.

20. The method of claim 19 wherein the first and the second adhesive layers include a pressure sensitive acrylic.
